(19) United States
(12) Patent Application Publication
(10) Pub. No.: US 2008/0278473 A1
(43) Pub. Date: Nov. 13, 2008

(54) Source line driver and method for controlling slew rate according to temperature and display device including the source line driver

(75) Inventor: Chang Ho An, Gyeonggi-do (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/151,756

(22) Filed: May 8, 2008

(30) Foreign Application Priority Data
May 11, 2007 (KR) 10-2007-0046012

(51) Int. Cl. G09G 5/10; H03K 3/00

(52) U.S. Cl. 345/214; 327/108

(57) ABSTRACT

A source line driver and method for controlling a slew rate according to temperature and a display device including the source line driver are provided. The source line driver includes a temperature sensing unit configured to sense a temperature, compare the sensed temperature with a reference temperature, and generate a comparison result as a control signal; and a bias voltage generator configured to output a plurality of bias voltages whose voltage levels are controlled in response to the control signal. Accordingly, the slew rate of an output buffer is controlled based on the sensed temperature, so that false operation caused by heat generated in the source line driver and display panel can be prevented when the temperature is increased.

### CROSS-REFERENCE TO RELATED PATENT APPLICATION

This application claims the benefit of Korean Patent Application No. 10-2007-0046012, filed on May 11, 2007, in the Korean Intellectual Property Office, the contents of which are incorporated herein in their entirety by reference.

### FIELD OF THE INVENTION

The present invention relates to a source line driver and a display device, and more particularly, to a source line driver and method for controlling a slew rate according to temperature and a display device including the source line driver.

### BACKGROUND OF THE INVENTION

FIG. 1 is a circuit diagram of a conventional source line driver 100. Referring to FIG. 1, the source line driver (or data line driver) 100 includes a digital-to-analog converter (DAC) 115, a bias voltage generator 400, a plurality of output buffers 200, a plurality of output switches TG10, and a plurality of charge-sharing switches TG12.

The DAC 115 generates analog voltages corresponding to input digital image data DATA. The bias voltage generator 400 provides a plurality of bias voltages V_{BN} and V_{BP} to each of the output buffers 200. Each of the output buffers 200 provides a display panel driving voltage to a corresponding data line Y₁, Y₂, . . . , Yₙ.

Each of the output switches TG10 transmits an output voltage of a corresponding output buffer 200 to a corresponding data line Y₁ through Yₙ in response to output switch control signals OSW and OSWB. The charge-sharing switches TG12 allow charges stored in loads (not shown) connected to the data lines Y₁ through Yₙ to be shared in response to sharing switch control signals CSSW and CSSWB so as to precharge a voltage of a data line driving signal to a predetermined precharge voltage.

FIG. 2 is a circuit diagram of an example of each output buffer 200 illustrated in FIG. 1. Referring to FIGS. 1 and 2, the output buffer 200 may include a folded cascode operational amplifier circuit 210 having a rail-to-rail input terminal structure and an output circuit 220 including a common drain amplifier and a compensation capacitor C.

The folded cascode operational amplifier circuit 210 amplifies a difference between a signal of a first input terminal Vin+ and a signal of a second input terminal Vin−. The output circuit 220 amplifies a signal output from the folded cascode operational amplifier circuit 210.

The folded cascode operational amplifier circuit 210 includes a PMOS current bias circuit 212 and an NMOS current bias circuit 214. The PMOS current bias circuit 212 includes a PMOS transistor MP1, which is driven by the bias voltage V_{BP} generated by the bias voltage generator 400 and provides a bias current I_{BP1} to the folded cascode operational amplifier circuit 210. The NMOS current bias circuit includes an NMOS transistor MN1, which is driven by the bias voltage V_{BN} generated by the bias voltage generator 400 and provides a bias current I_{BN1} to the folded cascode operational amplifier circuit 210. A slew rate of an output signal “output” of the output buffer 200 may be expressed by

$$\frac{( {I}_{BN 1} + {I}_{BP 1} )}{2 C} .$$

FIG. 3 is a circuit diagram of another example of each output buffer 200 illustrated in FIG. 1. Referring to FIGS. 1 and 3, the output buffer 200 may include a 2-stage NMOS operational amplifier circuit 230 and a 2-stage PMOS operational amplifier circuit 240.

The 2-stage NMOS operational amplifier circuit 230 includes an NMOS differential amplifier circuit 232 and an output circuit 234. The NMOS differential amplifier circuit 232 amplifies a difference between a signal of a first input terminal Vin+ and a signal of a second input terminal Vin−. A bias circuit 236 included in the NMOS differential amplifier circuit 232 includes an NMOS transistor MN2, which is driven by the bias voltage V_{BN} generated by the bias voltage generator 400 and provides a bias current I_{BN2} to the NMOS differential amplifier circuit 232.

The PMOS differential amplifier circuit 242 amplifies a difference between a signal of a first input terminal Vin+ and a signal of a second input terminal Vin−. A bias circuit 246 included in the PMOS differential amplifier circuit 242 includes a PMOS transistor MP2, which is driven by the bias voltage V_{BP} generated by the bias voltage generator 400 and provides a bias current I_{BP2} to the NMOS differential amplifier circuit 242.

The output circuits 234 and 244 include a compensation capacitor C and amplify signals respectively output from the differential amplifier circuits 232 and 242. A slew rate of the output signal “output” may be expressed by

$$\frac{{I}_{BN 2}}{C} or \frac{{I}_{BP 2}}{C} .$$

As described above, the slew rate of the output signal “output” of the source line driver 100 depends on the bias currents I_{BN1}, I_{BN2}, I_{BP1}, and I_{BP2} and the compensation capacitors C included in the output circuits 220, 234, and 244. Many characteristics of the source line driver 100 are determined by the output buffers 200 that output a driving voltage to a display panel. Of those characteristics, the slew rate of the output buffers 200 significantly affects a driving current in the source line driver 100. For instance, the slew rate of the output buffers 200 becomes faster as temperature increases. When the slew rate is too fast, current consumption of the output buffers 200 increases and a driving reference voltage of the display panel is distorted. That is, fluctuation occurs in the driving reference voltage of the display panel, which may induce false operation of a gate line driver.

In addition, as the temperature increases, the current consumption of the output buffers 200 also increases, and therefore, the temperature of the source line driver 100 is further increased. As a result, the display panel may erroneously operate due to the generation of heat.

### SUMMARY OF THE INVENTION

Some embodiments of the present invention provide a source line driver and method for controlling a slew rate of an output signal of an output buffer by sensing an internal temperature of the source line driver and controlling a bias voltage applied to the output buffer, and a display device including the source line driver.

According to one aspect, the present invention is directed to a source line driver including a digital-to-analog converter configured to generate an analog voltage corresponding to input digital image data; a temperature sensing unit configured to sense a temperature, compare the sensed temperature with a reference temperature, and generate a comparison result as a control signal; a bias voltage generator configured to output a plurality of bias voltages whose voltage levels are controlled in response to the control signal; and an output buffer configured to buffer the analog voltage output from the digital-to-analog converter based on the plurality of bias voltages. A slew rate of an output signal of the output buffer may be controlled based on the plurality of bias voltages.

The bias voltage generator may reduce the slew rate by decreasing a bias current of the output buffer when the temperature sensed by the temperature sensing unit is higher than the reference temperature.

The temperature sensing unit may include: a temperature sensor configured to sense the temperature, compare the sensed temperature with the reference temperature, and output the comparison result; and a latch configured to latch an output signal of the temperature sensor in response to a clock signal and output the latched signal as the control signal.

The bias voltage generator may include: a variable resistance circuit comprising a first node and a second node and having a resistance value varying in response to the control signal; and a bias voltage generation block configured to output the plurality of bias voltages based on signals output via the first node and the second node.

The variable resistance circuit may include: a first transistor connected with the first node and a third node and having a gate connected with the second node; a first switch switched in response to the control signal and connected between the third node and a fourth node; a first resistor connected between the fourth node and a first power supply voltage; and a second resistor connected between the third node and the fourth node via a second switch switched in response to the control signal. The first switch and the second switch may be complementarily switched in response to the control signal.

At least one between the first switch and the second switch may be implemented by a transmission transistor.

The bias voltage generation block may include: second through fourth transistors connected in series between a first power supply voltage and the first node; and fifth through eighth transistors connected in series between the first power supply voltage and a second power supply voltage. A gate of the second transistor, a gate of the fifth transistor, and a drain of the third transistor may be connected with one another. A gate of the third transistor may be connected with a gate of the sixth transistor. A gate of the fourth transistor may be connected with a gate of the seventh transistor. A drain of the seventh transistor and a gate of the eighth transistor may be connected with the second node. A first bias voltage among the plurality of bias voltages may be a gate voltage of the first transistor. A second bias voltage among the plurality of bias voltages may be a voltage of the second node.

The bias voltage generator may include: a variable resistance circuit comprising first through fifth nodes and having a resistance value varying in response to the control signal; and a bias voltage generation block configured to output the plurality of bias voltages based on signals output via the first through fifth nodes. The variable resistance circuit may include: a first transistor connected with the first node and a sixth node and having a gate connected with the second node; a first resistor connected between the sixth node and a first power supply voltage; a first switch switched in response to the control signal and connected between the third node and the fourth node; a second switch switched in response to the control signal and connected between the fourth node and a seventh node; a third switch switched in response to the control signal and connected between the third node and the first power supply voltage; a fourth switch connected with the fifth node and an eighth node and having a gate connected with the seventh node; a fifth switch connected to the eighth node and a ninth node and having a gate connected with the second node; a second resistor connected between the ninth node and the sixth node; and a sixth switch switched in response to the control signal and connected between the seventh node and the first power supply voltage. The first and sixth switches and the second and third switches may be complementarily switched in response to the control signal.

The bias voltage generation block may include: second through fourth transistors connected in series between a second power supply voltage and the first node; and fifth through eighth transistors connected in series between the first power supply voltage and the second power supply voltage. A gate of the second transistor, a gate of the fifth transistor, a drain of the third transistor, and the fourth switch may be connected with one another. A gate of the third transistor may be connected with a gate of the sixth transistor. A gate of the fourth transistor may be connected with the third node. A gate of the seventh transistor may be connected with the fourth node. A drain of the seventh transistor and a gate of the eighth transistor may be connected with the second node. A first bias voltage among the plurality of bias voltages may be a gate voltage of the second transistor. A second bias voltage among the plurality of bias voltages may be a voltage of the second node.

According to another aspect, the present invention is directed to a display device including: a display panel comprising a plurality of data lines and a plurality of gate lines, and a source line driver configured to drive the plurality of data lines. The source line driver may include: a digital-to-analog converter configured to generate an analog voltage corresponding to input digital image data; a temperature sensing unit configured to sense a temperature, compare the sensed temperature with a reference temperature, and generate a comparison result as a control signal; a bias voltage generator configured to output a plurality of bias voltages whose voltage levels are controlled in response to the control signal; and an output buffer configured to buffer the analog voltage output from the digital-to-analog converter based on the plurality of bias voltages. A slew rate of an output signal of the output buffer may be controlled based on the plurality of bias voltages.

The bias voltage generator may reduce the slew rate by decreasing a bias current of the output buffer when the temperature sensed by the temperature sensing unit is higher than the reference temperature.

The temperature sensing unit may include: a temperature sensor configured to sense the temperature, compare the sensed temperature with the reference temperature, and output the comparison result; and a latch configured to latch an output signal of the temperature sensor in response to a clock signal and output the latched signal as the control signal.

The bias voltage generator may include: a variable resistance circuit comprising a first node and a second node and having a resistance value varying in response to the control signal; and a bias voltage generation block configured to output the plurality of bias voltages based on signals output via the first node and the second node.

The variable resistance circuit may include: a first transistor connected with the first node and a third node and having a gate connected with the second node; a first switch switched in response to the control signal and connected between the third node and a fourth node; a first resistor connected between the fourth node and a first power supply voltage; and a second resistor connected between the third node and the fourth node via a second switch switched in response to the control signal. The first switch and the second switch may be complementarily switched in response to the control signal.

At least one of the first switch and the second switch may be implemented by a transmission transistor.

According to another aspect, the present invention is directed to a method of controlling a slew rate of an output signal of an output buffer included in a source line driver. The method includes generating an analog voltage corresponding to input digital image data; sensing a temperature, comparing the sensed temperature with a reference temperature, and generating a comparison result as a control signal; generating a plurality of bias voltages whose voltage levels can be controlled in response to the control signal; and buffering the analog voltage based on the plurality of bias voltages and outputting a buffered output signal. A slew rate of the buffered output signal may be controlled based on the plurality of bias voltages having controlled voltage levels.

The step of sensing the temperature, comparing the sensed temperature with the reference temperature, and generating the comparison result as the control signal may include: sensing the temperature, comparing the sensed temperature with the reference temperature, and outputting a comparison signal; and latching the comparison signal in response to a clock signal and outputting a latched signal as the control signal.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention.

FIG. 1 is a circuit diagram of a conventional source line driver.

FIG. 2 is a circuit diagram of an example of an output buffer illustrated in FIG. 1.

FIG. 3 is a circuit diagram of another example of the output buffer illustrated in FIG. 1.

FIG. 4 is a functional block diagram of a source line driver according to some embodiments of the present invention.

FIG. 5 is a circuit diagram of a temperature sensor illustrated in FIG. 4.

FIGS. 6A and 6B are graphs illustrating output characteristics of the temperature sensor illustrated in FIG. 4.

FIG. 7 is a circuit diagram of a bias voltage generator illustrated in FIG. 4, according to some embodiments of the present invention.

FIGS. 8 and 9 are circuit diagrams of a variable resistance circuit illustrated in FIG. 5, according to some embodiments of the present invention.

FIG. 10 is a circuit diagram of the bias voltage generator illustrated in FIG. 4, according to other embodiments of the present invention.

FIGS. 11A and 11B are waveform diagrams illustrating an output signal of an output buffer illustrated in FIG. 4.

FIG. 12 illustrates a display device including a source line driver according to some embodiments of the present invention.

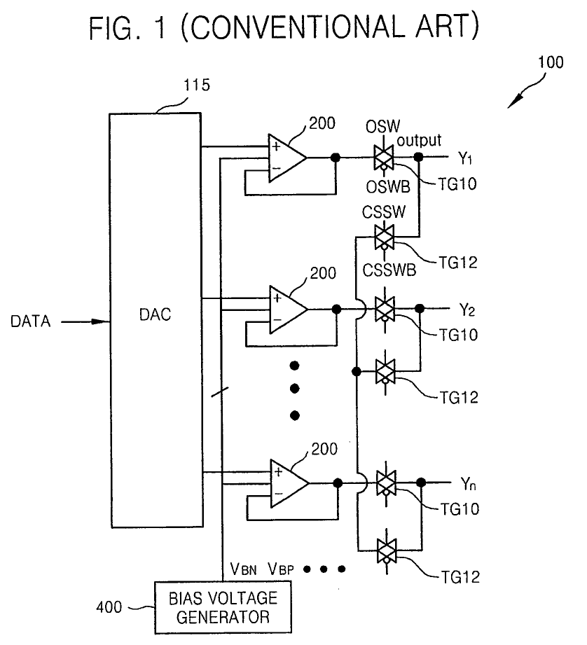

### DETAILED DESCRIPTION OF PREFERRED EMBODIMENTS

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this description will be thorough and complete, and will fully convey the scope of the invention to those skilled in the art. In the drawings, the size and relative sizes of layers and regions may be exaggerated for clarity.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

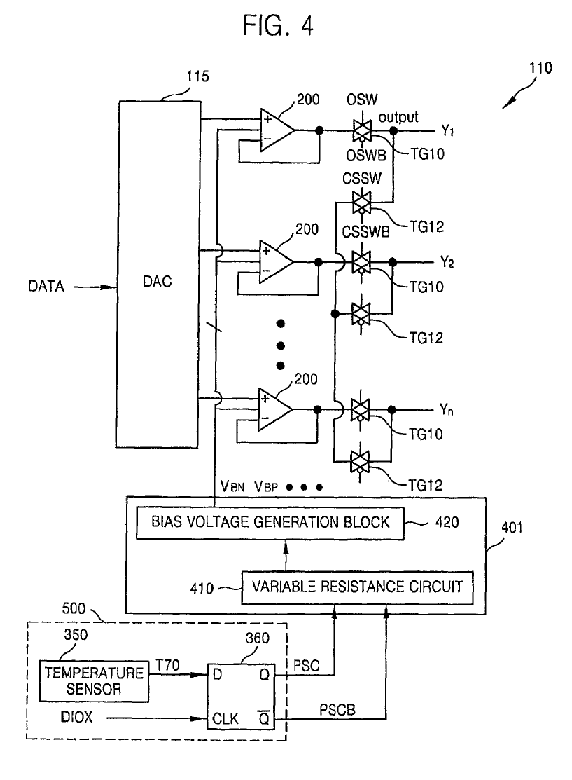

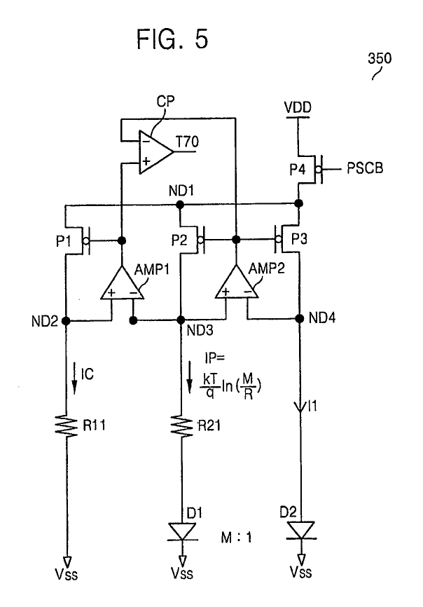

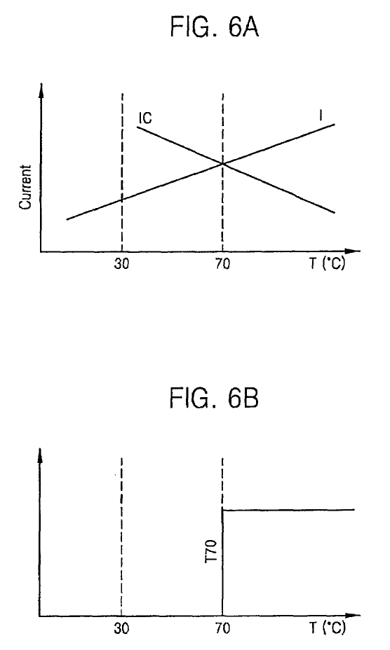

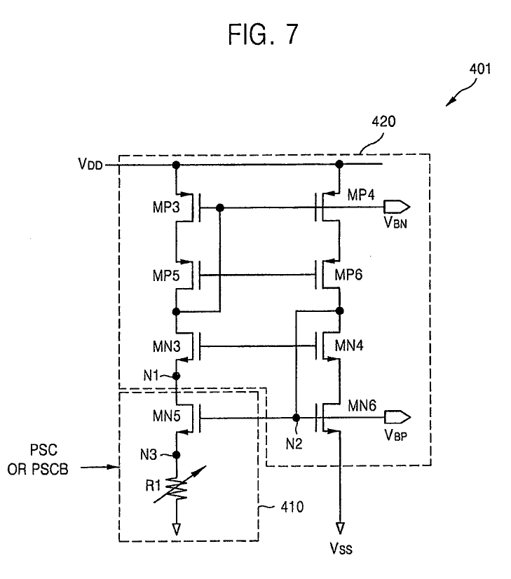

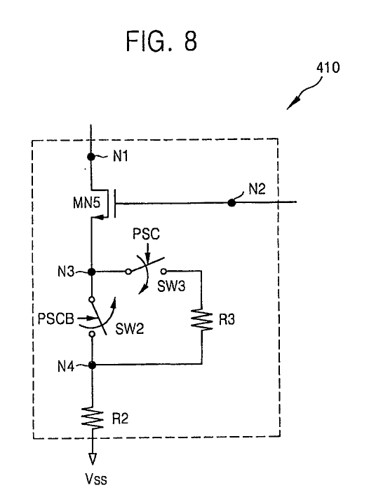

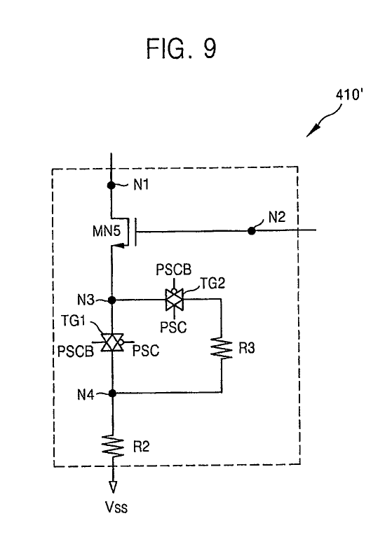

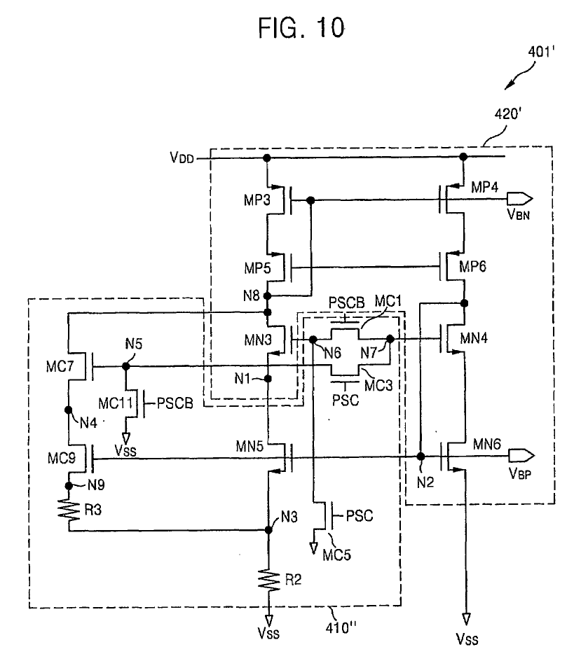

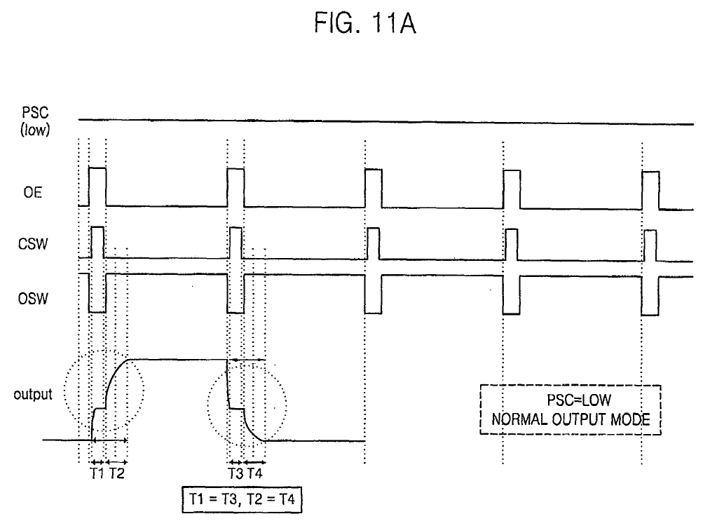

FIG. 4 is a functional block diagram of a source line driver 110 according to some embodiments of the present invention. FIG. 5 is a circuit diagram of a temperature sensor 350 illustrated in FIG. 4. FIGS. 6A and 6B are graphs illustrating output characteristics of the temperature sensor 350 illustrated in FIG. 4. FIG. 7 is a circuit diagram of a bias voltage generator 401 illustrated in FIG. 4, according to some embodiments of the present invention. FIGS. 8 and 9 are circuit diagrams of a variable resistance circuit 410 illustrated in FIG. 5, according to some embodiments of the present invention. FIG. 10 is a circuit diagram of the bias voltage generator 401 illustrated in FIG. 4, according to other embodiments of the present invention. Referring to FIGS. 4 through 10, the source line driver (or a source driver) 110 may include a digital-to-analog converter (DAC) 115, a plurality of output buffers 200, a plurality of output switches TG10, a plurality of charge-sharing switches TG12, a temperature sensing unit 500, and the bias voltage generator 401.

Upon receiving digital image data DATA, the DAC 115 generates an analog voltage corresponding to the digital image data DATA and outputs the analog voltage to the output buffers 200. The output buffers 200 supply a display panel driving voltage to data lines Y₁, Y₂, . . . , Yₙ, respectively.

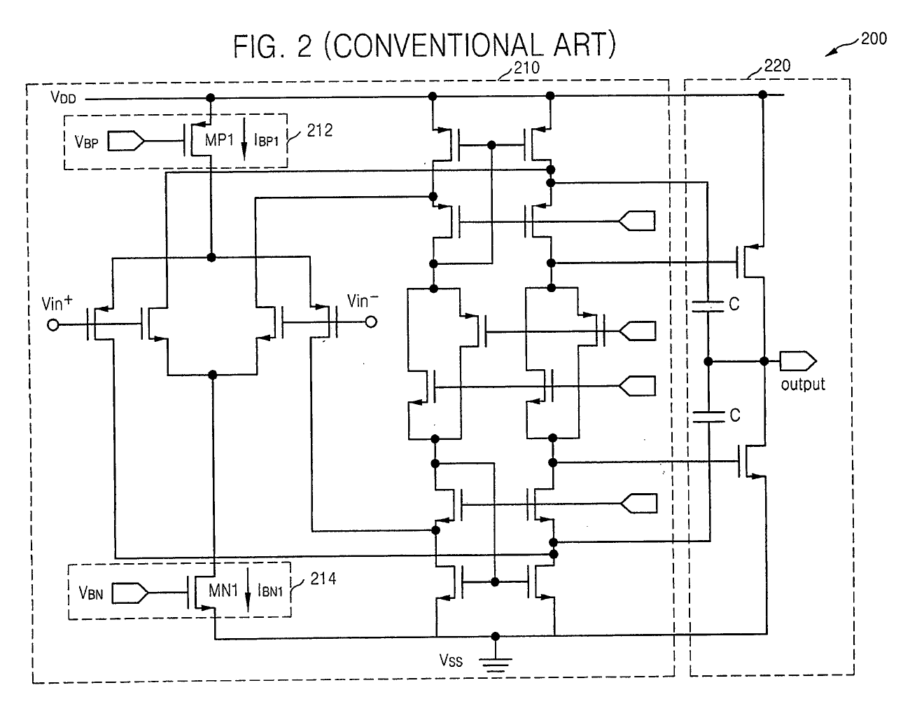

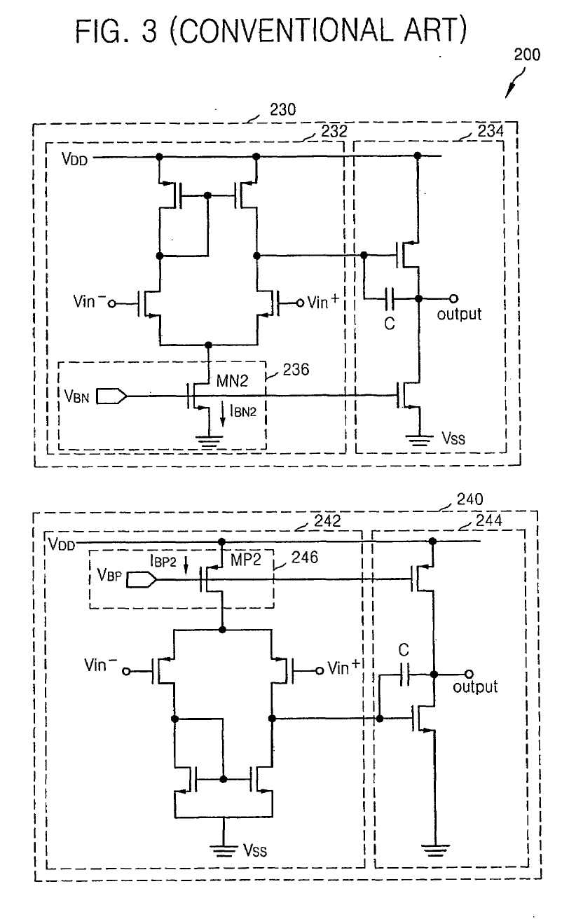

Each of the output switches TG10 transmits an output voltage of a corresponding output buffer 200 to a corresponding data line Y₁ through Yₙ in response to output switch control signals OSW and OSWB. Each of the output buffers 200 may include the folded cascode operational amplifier 210 illustrated in FIG. 2 or the 2-stage operational amplifiers 230 and 240 illustrated in FIG. 3.

The charge-sharing switches TG12 allow charges stored in loads (not shown) connected to the data lines Y₁ through Yₙ to be shared in response to sharing switch control signals CSSW and CSSWB so as to precharge a voltage of a data line driving signal to a predetermined precharge voltage. The precharge voltage may be VDD/2 when a voltage of a first data line driving signal and a voltage of a second data line driving signal are a complementary differential pair. That is, the voltage of a driving signal for each of the data lines Y₁ through Yₙ is precharged to the predetermined precharge voltage, and therefore, the burden of current supply on the output buffers 200 can be reduced.

The temperature sensing unit 500 senses a temperature, compares the sensed temperature with a reference temperature, and outputs the comparison result as a control signal PSC and/or PSCB. The temperature sensing unit 500 may include the temperature sensor 350 and a flip-flop 360.

The temperature sensor 350 may sense a temperature, compare the sensed temperature with the reference temperature, and outputs a comparison result T70. Referring to FIG. 5 and FIGS. 6A and 6B, the temperature sensor 350 may include PMOS transistors P1 through P4, a first diode D1, a second diode D2, a first amplifier AMP1, a second amplifier AMP2, and a comparator CP.

The first PMOS transistor P1 is gated with an output voltage of the first amplifier AMP1 so as to form a current path between a first node ND1 and a second node ND2. The second PMOS transistor P2 is gated with an output voltage of the second amplifier AMP2 so as to form a current path between the first node ND1 and a third node ND3. The third PMOS transistor P3 is gated with an output voltage of the second amplifier AMP2 so as to form a current path between the first node ND1 and a fourth node ND4. The fourth PMOS transistor P4 is gated with the second control signal PSCB so as to form a current path between a second power supply voltage VDD and the first node ND1.

A first resistor R11 may be connected between the first PMOS transistor P1 and a first power supply voltage Vss. A second resistor R21 and the first diode D1 may be connected in series between the second PMOS transistor P2 and the first power supply voltage Vss. The second diode D2 may be connected between the third PMOS transistor P3 and the first power supply voltage Vss.

The first amplifier AMP1 may differentially amplify a voltage of the second node ND2 and a voltage of the third node ND3 and output a result of the differential amplification to a gate of the first PMOS transistor P1. The second amplifier AMP2 may differentially amplify a voltage of the third node ND3 and a voltage of the fourth node ND4 and output a result of the differential amplification to a gate of the second PMOS transistor P2 and a gate of the third PMOS transistor P3. The comparator CP may compare the voltage output the first amplifier AMP1 with the voltage output from the second amplifier AMP2 and output the comparison result T70.

The temperature sensor 350 generates a reference current I (I=IP=I1) from a current I1 flowing across the fourth node ND4 and the second diode D2 and a current IP flowing across the third node ND3 and the first diode D1. When a ratio between a capacitance of the first diode D1 and a current of the second diode D2 is M:1, the reference current I may be expressed by I=kT/q*In(M/R). Here, “k” is the Boltzman constant, T is an absolute temperature, “q” is the amount of electron charges, and R is a resistance value of the second resistor R21. That is, reference current I increases in proportional to the absolute temperature T.

A current IC flowing in the first resistor R11 connected to the second node ND2 may be expressed by IC=V_{ND2}/R1. Here, V_{ND2} is a voltage induced in the second diode D2 and is a voltage of the fourth node ND4 or the second node ND2. At this time, when the absolute temperature T is increased, the voltage V_{ND2} is decreased, and therefore, the current IC flowing in the first resistor R11 is in reverse proportion to the absolute temperature T. As illustrated in FIG. 6A, the reference current I proportional to the absolute temperature T and the current IC reversely proportional to the absolute temperature T cross each other at a particular temperature (e.g., 70 degrees).

The output voltage of the first amplifier AMP1 corresponds to the magnitude of the current IC flowing in the first resistor R11 and the output voltage of the second amplifier AMP2 corresponds to the magnitude of the reference current I. The comparator CP may compare the output voltage of the first amplifier AMP1 with the output voltage of the second amplifier AMP2 and output the comparison result T70 according to whether the source line driver 110 has a temperature greater or less than a particular temperature (e.g., 70 degrees). For instance, the comparator CP may output as a temperature sensing result a comparison signal T70 at a first logic level (e.g., a low level of “0”) when the output voltage of the first amplifier AMP1 is greater than the output voltage of the second amplifier AMP2 as illustrated in FIG. 6B. When the output voltage of the first amplifier AMP1 is less than the output voltage of the second amplifier AMP2, that is, when the current IC is less than the current I, the comparator CP may output as the temperature sensing result the comparison signal T70 at a second logic level (e.g., a high level of “1”).

The flip-flop 360 includes an input terminal D receiving the output signal T70 of the temperature sensor 350, a clock terminal CK receiving a clock signal DIOX, an output terminal Q, and an inverting output terminal /Q. The flip-flop 360 may latch the output signal T70 of the temperature sensor 350 in response to the clock signal DIOX and output the latched signal as the control signal PSC and/or PSCB. In detail, among the control signals PSC and PSCB, the first control signal PSC may be at the second logic level (e.g., the high level of “1”) when the temperature sensed by the temperature sensor 350 is higher than a reference temperature and may be at the first logic level (e.g., the low level of “0”) when the temperature sensed by the temperature sensor 350 is lower than the reference temperature. The second control signal PSCB may have a phase difference of 180 degrees with respect to the first control signal PSC.

The clock signal DIOX may be generated by a timing controller (not shown) and indicate that the digital image data DATA has been input. The flip-flop 360 may be implemented by a latch (e.g., an S-R latch).

Referring back to FIG. 4, the bias voltage generator 401 provides a plurality of the bias voltages V_{BN} and V_{BP}, whose levels are controlled in response to the control signal PSC and/or PSCB, to each of the output buffers 200.

The bias voltage generator 401 includes the variable resistance circuit 410 and a bias voltage generation block 420. The variable resistance circuit 410 can control the levels of the bias voltages V_{BN} and V_{BP}, which are generated by the bias voltage generation block 420, in response to the control signal PSC or PSCB and controls the bias current of each of the output buffers 200 supplied with the controlled bias voltages, so that the slew rate of an output signal of each output buffer 200 can be controlled.

FIG. 7 is a circuit diagram of the bias voltage generator 401 illustrated in FIG. 4. Referring to FIG. 7, the bias voltage generator 401 includes the bias voltage generation block 420 and the variable resistance circuit 410 for controlling the bias voltage generation block 420. The variable resistance circuit 410 varies a resistance value in response to the control signal PSC or PSCB and the bias voltage generation block 420 outputs the bias voltages V_{BN} and V_{BP}, whose levels are controlled based on a signal of a first node N1 and a signal of a second node N2.

The bias voltages V_{BN} and V_{BP} are applied to the MOS transistor MP1 of the current bias circuit 212 and the MOS transistor MN1 of the current bias circuit 214 in the differential amplifier circuit 210 included in the output buffer 200 illustrated in FIG. 2 or to the MOS transistor MN2 of the current bias circuit 236 in the differential amplifier circuit 232 and the MOS transistor MP2 of the current bias circuit 246 in the differential amplifier circuit 242 in the output buffer 200 illustrated in FIG. 3. The bias voltages V_{BN} and V_{BP} can be controlled by the resistance value of the resistor R1 varying in response to the control signal PSC or PSCB, and therefore, the bias currents I_{BN1}, I_{BN2}, I_{BP1}, and I_{BP2} of the current bias circuits 212, 214, 236, and 246 in the output buffers 200 illustrated in FIGS. 2 and 3 can be controlled.

FIG. 8 illustrates the variable resistance circuit 410 illustrated in FIG. 5. The variable resistance circuit 410 includes a first transistor MN5, a first switch SW2, a second switch SW3, a first resistor R2, and a second resistor R3.

The first transistor MN5 is gated with a voltage of a second node N2 so as to form a current path between a first node N1 and a third node N3. The first switch SW2 is switched in response to the second control signal PSCB so as to form a current path between the third node N3 and a fourth node N4. The second resistor R3 is connected with the third node N3 and the fourth node N4 via the second switch SW3 switched in response to the first control signal PSC.

When a temperature sensed by the temperature sensor 350 is lower than the reference temperature and thus the first control signal PSC generated by the temperature sensing unit 500 is in a second logic state (e.g., a low level of “0”), that is, when the second control signal PSCB is in a first logic state (e.g., a high level of “1”), the first switch SW2 forms the current path between the third node N3 and the fourth node N4 and the second switch SW3 breaks the current path between the third node N3 and the third resistor R3. When a temperature sensed by the temperature sensor 350 is higher than the reference temperature and thus the first control signal PSC generated by the temperature sensing unit 500 is in the first logic state (e.g., the high level of “1”), that is, when the second control signal PSCB is in the second logic state (e.g., the low level of “0”), the first switch SW2 breaks the current path between the third node N3 and the fourth node N4 and the second switch SW3 forms the current path between the third node N3 and the third resistor R3. That is, when a temperature sensed by the temperature sensor 350 is higher than the reference temperature, the first resistor R2 and the second resistor R3 are connected in series and thus a resistance value between the third node N3 and the first power supply voltage Vss is increased. As a result, the bias voltage V_{BN} is decreased and the bias voltage V_{BP} is increased, and therefore, the bias currents I_{BN1}, I_{BN2}, I_{BP1}, and I_{BP2} of the current bias circuits 212, 214, 236, and 246 in the output buffers 200 illustrated in FIGS. 2 and 3 are decreased. Consequently, a slew rate is decreased.

According to the current embodiments of the present invention, the slew rate of the output buffer 200 can be controlled by varying the resistance value of the resistor R1 of the variable resistance circuit 410 included in the bias voltage generator 401 using the control signal PSC or PSCB generated based on the sensed temperature, thereby preventing false operation due to heat generation in the source line driver 110 and the display panel.

FIG. 9 is a circuit diagram of a variable resistance circuit 410′ according to other embodiments of the present invention. Here, the first switch SW2 and the second switch SW3 are implemented by transmission transistors TG1 and TG2, respectively. At this time, influence of switch on resistance can be reduced. The variable resistance circuit 410′ illustrated in FIG. 9 is the same as the variable resistance circuit 410 illustrated in FIG. 8, with the exception that the first and second switches SW2 and SW3 illustrated in FIG. 8 are implemented by the transmission transistors TG1 and TG2, respectively.

Referring back to FIG. 7, the bias voltage generation block 420 may include the first node N1, the second node N2, second through fourth transistors MP3, MP5, and MN3 connected in series between the second power supply voltage VDD and the first node N1, and fifth through eighth transistors MP4, MP6, MN4, and MN6 connected in series between the first power supply voltage Vss and the second power supply voltage VDD. A gate of the second transistor MP3, a gate of the fifth transistor MP4, and a drain of the third transistor MP5 may be connected with one another. A gate of the third transistor MP5 may be connected with a gate of the sixth transistor MP6. A gate of the fourth transistor MN3 may be connected with a gate of the seventh transistor MN4. A drain of the seventh transistor MN4 and a gate of the eighth transistor MN6 may be connected with the second node N2. The first bias voltage V_{BN} may be a gate voltage of the second transistor MP3 and the second bias voltage V_{BP} may be a voltage of the second node N2.

FIG. 10 is a circuit diagram of a bias voltage generator 401′ according to other embodiments of the present invention. The bias voltage generator 401′ may include a variable resistance circuit 410″, which includes first through fifth nodes N1, N3, N4, N5, and N9, and a bias voltage generation block 420′, which outputs the bias voltages V_{BN} and V_{BP} based on signals output via the first node N1 and sixth through ninth nodes N2, N6, N7, and N8.

The variable resistance circuit 410″ may include the first transistor MN5, the first resistor R2, the second resistor R3, and first through sixth switches MC1, MC3, MC5, MC7, MC9, and MC11. The first transistor MN5 may be connected between the first node N1 and a second node N3 and have a gate connected with the sixth node N2. The first resistor R2 may be connected between the second node N3 and the first power supply voltage Vss. The second resistor R3 may be connected between a fifth node N9 and the fourth node N3. The first switch MC1 may be switched in response to the second control signal PSCB and may be connected between the seventh node N6 and the eighth node N7.

The second switch MC3 may be switched in response to the first control signal PSC and may be connected between the eighth node N7 and the fourth node N5. The third switch MC5 may be switched in response to the first control signal PSC and may be connected between the seventh node N6 and the first power supply voltage Vss. The fourth switch MC7 may be connected between the ninth node N8 and a third node N4 and may have a gate connected with the fourth node N5. The fifth switch MC9 may be connected between the third node N4 and a fifth node N9 and may have a gate connected with the sixth node N2. The sixth switch MC11 may be switched in response to the second control signal PSCB and may be connected between the fourth node N5 and the first power supply voltage Vss. The first and sixth switches MC1 and MC11 and the second and third switches MC3 and MC5 may be complementarily switched in response to the second and first control signals PSCB and PSC, respectively.

The bias voltage generation block 420′ outputs the bias voltages V_{BN} and V_{BP} based on the signals output via the first node N1 and sixth though ninth nodes N2, N6, N7, and N8. The bias voltage generation block 420′ may include second through fourth transistors MP3, MP5, and MN3 connected in series between the second power supply voltage VDD and the first node N1 and fifth through eighth transistors MP4, MP6, MN4, and MN6 connected in series between the first power supply voltage Vss and the second power supply voltage VDD.

A gate of the second transistor MP3, a gate of the fifth transistor MP4, a drain of the third transistor MP5, and the fourth switch MC7 may be connected with one another. A gate of the third transistor MP5 and a gate of the sixth transistor MP6 may be connected with each other. A gate of the fourth transistor MN3 may be connected with the seventh node N6. A gate of the seventh transistor MN4 may be connected with the eighth node N7. A drain of the seventh transistor MN4 and a gate of the eighth transistor MN5 may be connected with the sixth node N2.

The first bias voltage V_{BN} may be a gate voltage of the second transistor MP3 and the second bias voltage V_{BP} may be a voltage of the sixth node N2. When a temperature sensed by the temperature sensor 350 is lower than the reference temperature and thus the first control signal PSC generated by the temperature sensing unit 500 is in the second logic state (e.g., the low level of “0”), that is, when the second control signal PSCB is in the first logic state (e.g., the high level of “1”), the first and sixth switches MC1 and MC11 are turned on and the second and third switches MC3 and MC5 are turned off. When a temperature sensed by the temperature sensor 350 is higher than the reference temperature and thus the first control signal PSC generated by the temperature sensing unit 500 is in the first logic state (e.g., the high level of “1”), that is, when the second control signal PSCB is in the second logic state (e.g., the low level of “0”), the first and sixth switches MC1 and MC11 are turned off and the second and third switches MC3 and MC5 are turned on. That is, when a temperature sensed by the temperature sensor 350 is higher than the reference temperature, the fourth and fifth switches MC7 and MC9 are gated to connect the first resistor R2 and the second resistor R3 in series and thus a resistance value between the eighth node N4 and the first power supply voltage Vss is increased. As a result, the bias voltage V_{BN} is decreased and the bias voltage V_{BP} is increased, and therefore, the bias currents I_{BN1}, I_{BN2}, I_{BP1}, and I_{BP2}_{_{—}}of the current bias circuits 212, 214, 236, and 246 in the output buffers 200 illustrated in FIGS. 2 and 3 are decreased. Consequently, a slew rate is decreased.

According to the current embodiments of the present invention, the slew rate of the output buffer 200 can be controlled by varying the resistance value of the resistor R1 of the variable resistance circuit 410 included in the bias voltage generator 401 using the control signal PSC or PSCB generated based on the sensed temperature, thereby preventing false operation duet to heat generation in the source line driver 110 and the display panel.

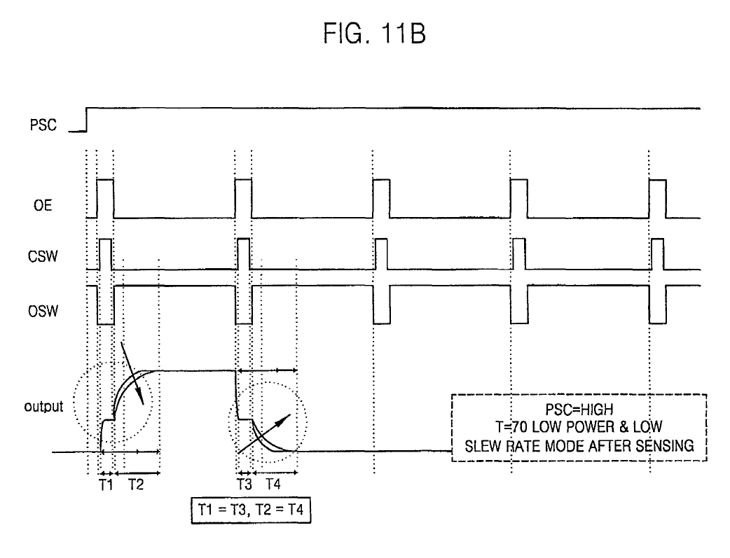

FIGS. 11A and 11B are waveform diagrams illustrating an output signal of each output buffer 200 illustrated in FIG. 4. FIG. 11A shows the waveform of the output signal of the output buffer 200 when a temperature of the source line driver 110 is lower than a particular temperature (e.g., 70 degrees). Periods T1 and T3 indicate charge sharing times of a display panel cell and periods T2 and T4 indicate slew rate times following the charge sharing times.

In FIGS. 11A and 11B, “output” refers to the output signal of the output buffer 200, which is transmitted to a display panel (not shown). When the temperature of the source line driver 110 is lower than the particular temperature (e.g., 70 degrees), that is, when the first control signal PSC is in the first logic state (e.g., the low level of “0”), the slew rate of the output buffer 200 is output as it is without being controlled as illustrated in FIG. 11A. Contrarily, when the temperature of the source line driver 110 is higher than the particular temperature (e.g., 70 degrees), that is, when the first control signal PSC is in the second logic state (e.g., the high level of “1”), the output signal of the output buffer 200 has the waveform illustrated in FIG. 11B. As illustrated in FIG. 11B, the slew rate of the output buffer 200 is controlled in an arrowhead direction so as to be maintained low. Accordingly, the false operation that may be induced by heat generation in the source line driver 110 and the display panel may be prevented when the temperature is increased.

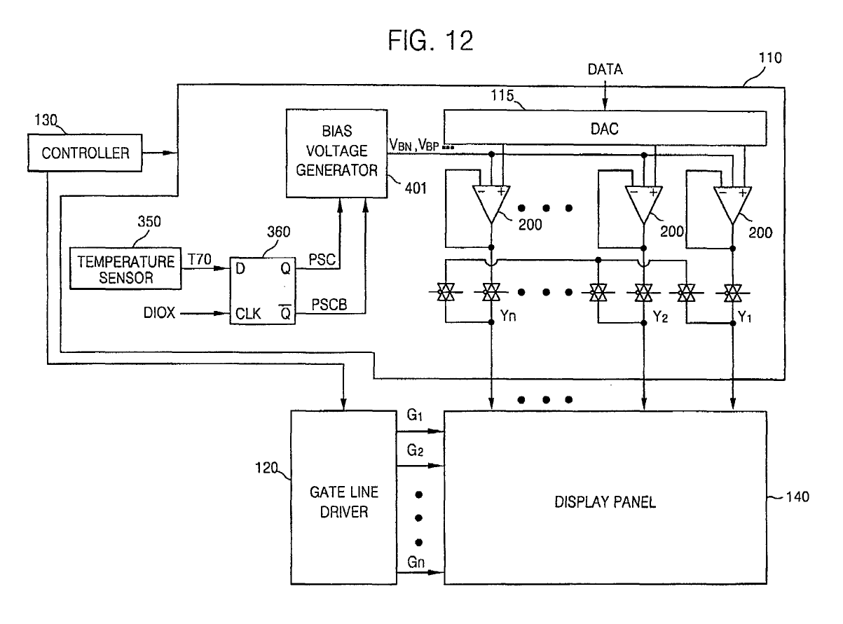

FIG. 12 illustrates a display device including the source line driver 110 according to some embodiments of the present invention. The display device includes the source line driver 110, a gate line driver 120, a controller 130, and a display panel 140.

The source line driver 110 provides a driving voltage to a plurality of data lines Y₁ through Yₙ. The gate line driver 120 provides a voltage to a plurality of gate lines G₁ through Gₙ. The source line driver 110 may include a DAC 115, output buffers 200, and a bias voltage generator 401. The source line driver 110 has been described in detail with reference to FIGS. 4 through 11B. Thus, detailed descriptions thereof will not be repeated.

The controller 130 controls the source line driver 110 and the gate line driver 120. The display panel 140 includes the plurality of gate lines G₁ through Gₙ and the plurality of data lines Y₁ through Yₙ and is driven by the source line driver 110 and the gate line driver 120 so as to display an image.

As described above, according to some embodiments of the present invention, the slew rate of an output buffer included in a source line driver of a display panel is controlled based on a sensed temperature, thereby preventing false operation that may be caused by heat generated in the source line driver and a display panel when the temperature is increased.

While the present invention has been shown and described with reference to exemplary embodiments thereof, it will be understood by those of ordinary skill in the art that various changes in form and detail may be made herein without departing from the spirit and scope of the present invention, as defined by the following claims.

What is claimed is:

1. A source line driver comprising:
a digital-to-analog converter configured to generate an analog voltage corresponding to input digital image data;
a temperature sensing unit configured to sense a temperature, compare the sensed temperature with a reference temperature, and generate a comparison result as a control signal;
a bias voltage generator configured to output a plurality of bias voltages whose voltage levels are controlled in response to the control signal; and
an output buffer configured to buffer the analog voltage output from the digital-to-analog converter based on the plurality of bias voltages,
wherein a slew rate of an output signal of the output buffer is controlled based on the plurality of bias voltages.

2. The source line driver of claim 1, wherein the bias voltage generator reduces the slew rate by decreasing a bias current of the output buffer when the temperature sensed by the temperature sensing unit is higher than the reference temperature.

3. The source line driver of claim 1, wherein the temperature sensing unit comprises:
a temperature sensor configured to sense the temperature, compare the sensed temperature with the reference temperature, and output the comparison result; and
a latch configured to latch an output signal of the temperature sensor in response to a clock signal and output the latched signal as the control signal.

4. The source line driver of claim 1, wherein the bias voltage generator comprises:
a variable resistance circuit comprising a first node and a second node and having a resistance value varying in response to the control signal; and
a bias voltage generation block configured to output the plurality of bias voltages based on signals output via the first node and the second node.

5. The source line driver of claim 4, wherein the variable resistance circuit comprises:
a first transistor connected with the first node and a third node and having a gate connected with the second node;
a first switch switched in response to the control signal and connected between the third node and a fourth node;
a first resistor connected between the fourth node and a first power supply voltage; and
a second resistor connected between the third node and the fourth node via a second switch switched in response to the control signal, and wherein the first switch and the second switch are complementarily switched in response to the control signal.

6. The source line driver of claim 5, wherein at least one of the first switch and the second switch is implemented by a transmission transistor.

7. The source line driver of claim 4, wherein the bias voltage generation block comprises:
second through fourth transistors connected in series between a first power supply voltage and the first node; and
fifth through eighth transistors connected in series between the first power supply voltage and a second power supply voltage,
wherein a gate of the second transistor, a gate of the fifth transistor, and a drain of the third transistor are connected with one another,
wherein a gate of the third transistor is connected with a gate of the sixth transistor,
wherein a gate of the fourth transistor is connected with a gate of the seventh transistor,
wherein a drain of the seventh transistor and a gate of the eighth transistor are connected with the second node,
wherein a first bias voltage among the plurality of bias voltages is a gate voltage of the first transistor, and
wherein a second bias voltage among the plurality of bias voltages is a voltage of the second node.

8. The source line driver of claim 1, wherein the bias voltage generator comprises:
a variable resistance circuit comprising first through fifth nodes and having a resistance value varying in response to the control signal; and
a bias voltage generation block configured to output the plurality of bias voltages based on signals output via the first through fifth nodes,
wherein the variable resistance circuit comprises:
a first transistor connected with the first node and a sixth node and having a gate connected with the second node;
a first resistor connected between the sixth node and a first power supply voltage;
a first switch switched in response to the control signal and connected between the third node and the fourth node;
a second switch switched in response to the control signal and connected between the fourth node and a seventh node;
a third switch switched in response to the control signal and connected between the third node and the first power supply voltage;
a fourth switch connected with the fifth node and an eighth node and having a gate connected with the seventh node;
a fifth switch connected to the eighth node and a ninth node and having a gate connected with the second node;
a second resistor connected between the ninth node and the sixth node; and
a sixth switch switched in response to the control signal and connected between the seventh node and the first power supply voltage, and
wherein the first and sixth switches and the second and third switches are complementarily switched in response to the control signal.

9. The source line driver of claim 8, wherein the bias voltage generation block comprises:
second through fourth transistors connected in series between a second power supply voltage and the first node; and
fifth through eighth transistors connected in series between the first power supply voltage and the second power supply voltage,
wherein a gate of the second transistor, a gate of the fifth transistor, a drain of the third transistor, and the fourth switch are connected with one another,
wherein a gate of the third transistor is connected with a gate of the sixth transistor,
wherein a gate of the fourth transistor is connected with the third node,
wherein a gate of the seventh transistor is connected with the fourth node,
wherein a drain of the seventh transistor and a gate of the eighth transistor are connected with the second node,
wherein a first bias voltage among the plurality of bias voltages is a gate voltage of the second transistor, and
wherein a second bias voltage among the plurality of bias voltages is a voltage of the second node.

10. A display device comprising:
a display panel comprising a plurality of data lines and a plurality of gate lines; and
a source line driver configured to drive the plurality of data lines,
wherein the source line driver comprises:
a digital-to-analog converter configured to generate an analog voltage corresponding to input digital image data;
a temperature sensing unit configured to sense a temperature, compare the sensed temperature with a reference temperature, and generate a comparison result as a control signal;
a bias voltage generator configured to output a plurality of bias voltages whose voltage levels are controlled in response to the control signal; and
an output buffer configured to buffer the analog voltage output from the digital-to-analog converter based on the plurality of bias voltages, and
wherein a slew rate of an output signal of the output buffer is controlled based on the plurality of bias voltages.

11. The display device of claim 10, wherein the bias voltage generator reduces the slew rate by decreasing a bias current of the output buffer when the temperature sensed by the temperature sensing unit is higher than the reference temperature.

12. The display device of claim 10, wherein the temperature sensing unit comprises:
a temperature sensor configured to sense the temperature, compare the sensed temperature with the reference temperature, and output the comparison result; and
a latch configured to latch an output signal of the temperature sensor in response to a clock signal and output the latched signal as the control signal.

13. The display device of claim 10, wherein the bias voltage generator comprises:
a variable resistance circuit comprising a first node and a second node and having a resistance value varying in response to the control signal; and
a bias voltage generation block configured to output the plurality of bias voltages based on signals output via the first node and the second node.

14. The display device of claim 13, wherein the variable resistance circuit comprises:
a first transistor connected with the first node and a third node and having a gate connected with the second node;
a first switch switched in response to the control signal and connected between the third node and a fourth node;
a first resistor connected between the fourth node and a first power supply voltage; and
a second resistor connected between the third node and the fourth node via a second switch switched in response to the control signal, and
wherein the first switch and the second switch are complementarily switched in response to the control signal.

15. The display device of claim 14, wherein at least one of the first switch and the second switch is implemented by a transmission transistor.

16. A method of controlling a slew rate of an output signal of an output buffer included in a source line driver, the method comprising:
generating an analog voltage corresponding to input digital image data;
sensing a temperature, comparing the sensed temperature with a reference temperature, and generating a comparison result as a control signal;
generating a plurality of bias voltages whose voltage levels can be controlled in response to the control signal; and
buffering the analog voltage based on the plurality of bias voltages and outputting a buffered output signal,
wherein a slew rate of the buffered output signal is controlled based on the plurality of bias voltages having controlled voltage levels.

17. The method of claim 16, wherein the operation of sensing the temperature, comparing the sensed temperature with the reference temperature, and generating the comparison result as the control signal comprises:
sensing the temperature, comparing the sensed temperature with the reference temperature, and outputting a comparison signal; and
latching the comparison signal in response to a clock signal and outputting a latched signal as the control signal.
